(19) United States
(12) Patent Application Publication
(10) Pub. No.: US 2003/0193418 A1
(43) Pub. Date: Oct. 16, 2003

(54) Method and Apparatus To Input Text On Devices Requiring A Small Keypad

(76) Inventor: Xiaodong Shi, Sunnyvale, CA (US)

Correspondence Address: SIMPOWL INC., 956 AZURE ST #2, SUNNYVALE, CA, 94087, US

(21) Appl. No.: 10/249,434

(22) Filed: Apr. 8, 2003

Related U.S. Application Data
(60) Provisional application No. 60/319,177, filed on Apr. 10, 2002.

(51) Int. Cl. H03K 17/94; H03M 11/00

(52) U.S. Cl. 341/22

(57) ABSTRACT

The invention presents a method to input text on a legacy alphanumeric keypad upon which no substantial changes involved. On such a keypad keys are normally shared by four or more characters, creating an ambiguity thus inefficiency. This method introduces shift keys on the side or back of the keypad body, which can be pressed by fingers otherwise only serving to hold or support the device, together with any regular key actuated by the thumb to generate the intended input. This reduces the time needed to resolve the ambiguity and can be done conveniently by natural participation of other fingers from the same hand. Two shift keys can be pressed together to function as a third shift key to further reduce the complexity.

### CROSS REFERENCE TO RELATED APPLICATIONS

This patent application claims benefits of and priority from U.S. provisional patent application No. 60/319,177, filed Apr. 10, 2002.

### BACKGROUND OF INVENTION

Mobile personal devices, like handhelds or cell phones are providing people with more and more convenience, as more and more they are light in weight, small in size, flexible in manipulation and powerful in functionality. Yet there lies a big difficulty or bottleneck toward making it ultimately convenient: inputting data, or inputting text. The prevailing way nowadays to input data into electronic devices are using keyboard/mouse, but by its nature, a mobile device can only be attached with relatively small inputting elements.

Existing design and inventions to address this problem fall into two categories: using a keyboard or using a keypad. The former includes reducing the size of the keyboard or make it transferable—e.g. foldable—to make it mobile. But essentially a keyboard with all the keys on can not achieve the same mobility cell phones possessing.

To instead use a keypad with limited number of keys on, each key must carry multiple characters, followed that there must be a method to resolve the ambiguity, i.e. to determine which one is entered at the time a key is pressed. There are prior arts as following:

1. By the number of presses on a key, as seen in most of today's cellular phones

2. By displaying possibilities on the screen and let the user to choose further (U.S. Pat. No. 6,346,894)

3. By pressing different area of a key (U.S. Pat. No. 6,541,715)

4. By different levels of pressure applied on a key (U.S. Pat. No. 6,307,537)

5. By pressing at the same time adjacent keys together (U.S. Pat. No. 5,973,621)

6. By working with a dedicated N-way switch key where N>=2, where N being at least 3 in reality (U.S. Pat. No. 6,528,741)

Each of the above methods could possibly solve or have been used to solve the problem of inputting texts by a keypad, but they added considerable complexity and inefficiency too, which consequently reduced the convenience and the ultimate usability of the original device. Specifically,

Method 1: too many presses needed to input one single character. In the worst case this number is 5;

Method 2: similar to Method 1, plus the response time to generate and display the options on the screen. Potentially slow;

Method 3: essentially increasing the number of keys physically and not reliable, considering the size of a finger and the dimension of the keys;

Method 4: may not be easy to use in reality and as a de facto variation of Method 1 may inherit all its shortcomings;

Method 5: could be very complicated and error-prone, considering mapping 10 keys to 36 alphanumeric characters when capitalization excluded;

Method 6: practically must operate with both hands and involves constant movements of another finger besides a thumb. Considerable space is also needed to allocate the switch key.

Nevertheless, We need to have an input method matching the simplicity and efficiency mobile devices already have.

### BRIEF DESCRIPTION OF DRAWINGS

FIG. 1 is a front view of a cellular phone with two shift keys on the side as an embodiment of the invention. With two such keys, plus actuated together forming a third one, 10 regular keys can generate 40 character outputs equally by the time of one press, which is enough to cover 10 numbers and 26 letters;

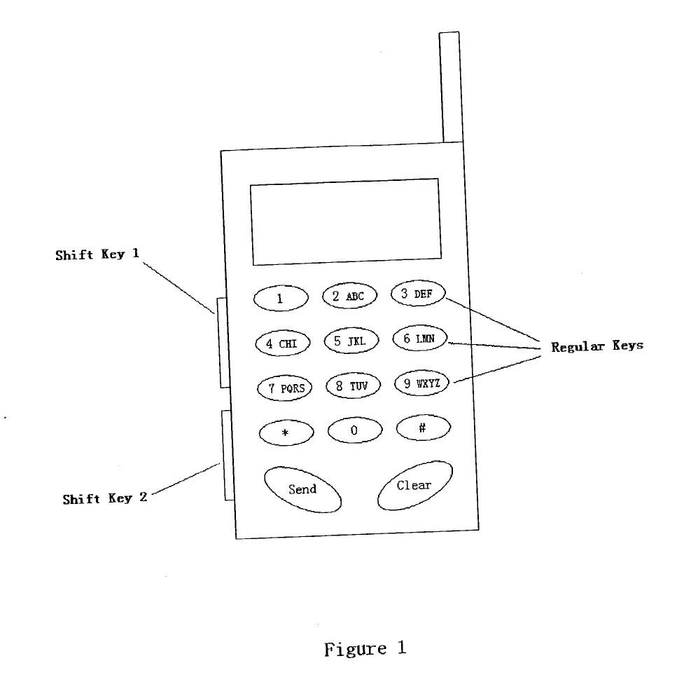

FIG. 2 illustrates the embodiment of the invention mentioned in FIG. 1 being held in a human hand. The middle and the third finger naturally rest on the two shift keys, enabling users to operate conveniently and comfortably.

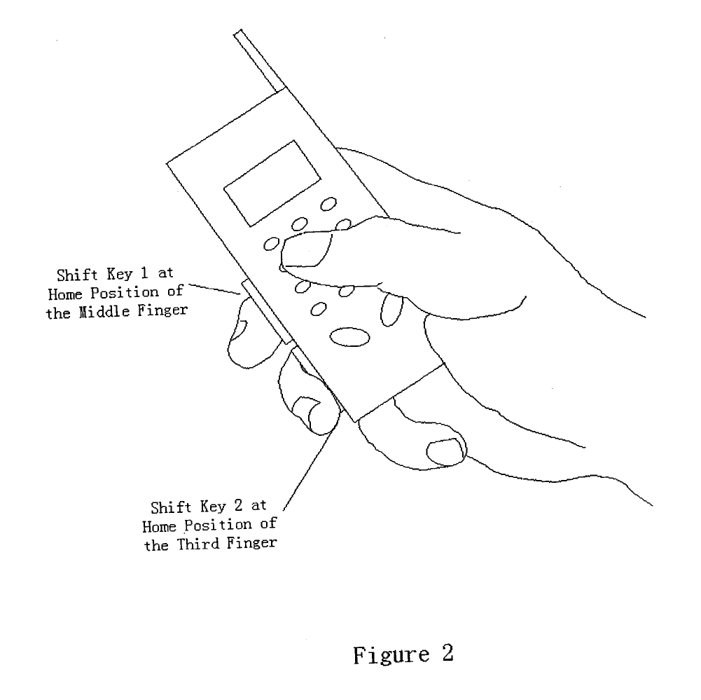

FIG. 3 is a back view of a cellular phone with the surface concaved to allocate a shift key on the bottom. Instead of having a flat surface thus shift-key press happens in the direction of back to front, this design allows it to be in the top-down direction without causing movements of the phone body. The concaved part is preferred to be home position of the forefinger.

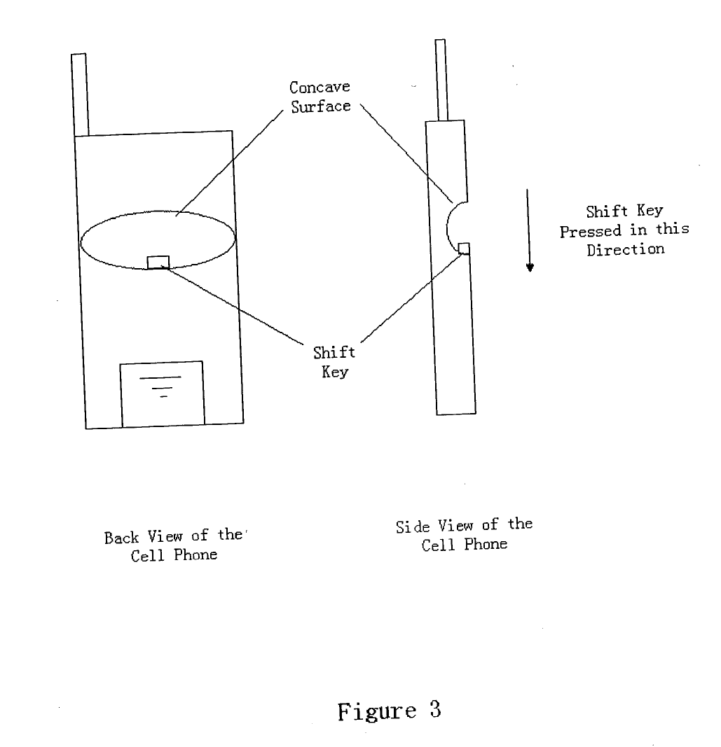

### DETAILED DESCRIPTION

By studying on cell phones and similar devices, it could be observed that at least three fingers are always required in the device operation. Normally a thumb presses buttons, and the middle and the third finger together with the palm play the role of holding the device. In the case of using the right hand, the middle and the third finger are placed on the left side and the palm on the right. The little finger is usually placed under the device to provide extra support, although that may not always be necessary.

For devices even smaller, often only the middle finger is placed on the left side. But in this case the forefinger is there to form another strong support, consequently there are still three fingers in participation.

As it can be seen, two fingers in the operation now only have limited usages of holding and supporting. The thumb is the only one doing the actual inputting. If all fingers participate key-pressing the task could be made easier. This is possible as the fingertips still have the flexibility and freedom to press a button as other part of the finger holding the device. If two special buttons placed on the position where they can naturally access, the original issues may be solved. This leads to the idea of Shift keys there, which functions similar to such keys on a regular keyboard. Unlike on a keyboard where one key is shared at most by two characters, more Shift keys are necessary for a keypad on which one key is typically shared by four characters.

In detail, a button can be just provided at each position where a supporting finger normally rests on, the side or the back of the device, and make the button function to shift a regular key, i.e. it doesn't generate any output when pressed alone but it alters the output of another key when pressed together. For example, letters A, B and C shares the same key with the digit 2 on a legacy keypad. Pressing it alone means 2, pressing it together with one shift key would mean A, with another shift key would mean B. Note that pressing a shift key and a regular key together, like its counterpart on a keyboard, means that the shift key must be pressed on or before the moment a regular key is pressed and held until the input generated. ile. when the regular key is being pressed the shift key must be in the state of engagement.

Besides working separately, two shift keys pressed together can function as a third shift key. This solves the problem to select out the letter C without introducing another physical shift key. Similarly, if selection of the letter F is desired, it can be achieved by pressing ‘3’ with both shift keys pressed and held, etc.

This method has several apparent advantages: it doesn't require any rearrangement of keys on a legacy keypad, it doesn't involving much extra operational efforts, it enables inputting any alphanumeric character by the time of one press, and finally, these can all be done by a single hand.

Here are some possible embodiments. First, shift keys may be placed on the right side of the device too besides ones on the left, as people may use the left hand to operate the device. Second, some indications may be provided real-time to assist the use of shift keys. For example, if a shift key is pressed, all the letters or symbols it corresponds to would be highlighted on the keypad, either electronically or mechanically. Third, pressing a button on the back of the device or using a weakly supporting finger to press a button may break the balance of the device. However, if the shape is made convex or concave instead of flat, the direction of button-pressing may be altered for stable operations. Fourth, more shift keys may be available thus also more combinations, and they may be placed anywhere on the keypad. With N shift keys and M regular keys, there are maximally 2^{N}×M achievable characters or symbols. Last, on a legacy keypad there are keys shared by 5 characters, such as ‘7’ and ‘9’, but minor rearrangement or may easily solve the problem, if noticing ‘1’ and ‘0’ are not shared at all.

This method can also be applied on devices other than mobile phones or palmtops, such as remote control devices where text inputs may also be involved.

1. A portable electronic device with a part to input or select characters, including:
A plurality of shift keys and a plurality of regular keys with said regular keys each have a set of characters assigned thereto;
Wherein each said regular keys, when actuated alone, inputs one character out of its assigned character set;
Wherein said shift keys, when actuated alone, do not generate character inputs;
Wherein actuating a said shift key along with a said regular key inputs one character out of the regular key's assigned character set. Herein actuating a shift key along with a regular key means that actuating the regular key while the shift key actuated and held;
Wherein two or more said shift keys, when actuated together, do not generate character inputs;
Wherein actuating two or more said shift keys along with a said regular key inputs one character out of the regular key's assigned character set. Herein actuating shift keys along with a regular key means that actuating the regular key while all said shift keys actuated and held;
Wherein said characters can be alphanumeric characters, special characters, or control inputs.

2. The device according to claim 1, wherein said input part contains a standard telephone keypad layout which has three said regular key columns, of which a left column containing 1, 4, 7, a middle column containing 2, 5, 8, 0, and a right column containing 3, 6, 9.

3. The device according to claim 2, wherein one said shift key is placed at the home position of the first finger when holding the device, either on its side, back or the corner.

4. The device according to claim 2, wherein one said shift key is placed at the home position of the middle finger when holding the device, either on its side, back or the corner.

5. The device according to claim 2, wherein one said shift key is placed at the home position of the third finger when holding the device, either on its side, back or the corner.

6. The device according to claim 2, wherein one said shift key is placed at the home position of the little finger when holding the device, either on its side, back or the corner.

7. The device according to claim 2, wherein two said shift keys are placed at the home positions of the first finger and the middle finger when holding the device, either on its side, back or the corner.

8. The device according to claim 2, wherein two said shift keys are placed at the home positions of the middle finger and the third finger when holding the device, either on its side, back or the corner.

9. The device according to claim 2, wherein three said shift keys are placed at the home positions of the first finger, the middle finger and the third finger when holding the device, either on its side, back or the corner.

10. The device according to claim 9, wherein the shift key on the home position of the first finger works as a caps lock key, i.e. actuation of it toggles between locked/unlocked mode which effects the letter inputs to be uppercase/lower-case.

11. The device according to claim 1, wherein said shift keys, when actuated alone or together a plurality of times, generate character inputs.

12. The device according to claim 1, wherein a plurality of said shift keys work as switch keys, i.e. when actuated then released it locks its shifting effects until the next time actuated to unlock.

13. The device according to claim 1, wherein different shift keys or shift key combinations shifts out a different character input out of the assigned character set of a together actuated regular key.

14. The device according to claim 1, wherein a shift key or shift key combination effects to switch between upper- and lower-case of letters.

15. The device according to claim 1, wherein said regular keys have indications on them showing their assigned character set.

16. The device according to claim 15, wherein the corresponding characters of said indications highlight according to and during the shift key or shift key combination actuated.

17. The device according to claim 1, wherein said device has a screen and said regular keys have indications on the screen changing their appearances according to the shift key or shift key combination actuated.

18. The device according to claim 1, wherein said device has convex or concave area on its back and/or sides with a plurality of shift keys embedded in.
